(19) United States
(12) Patent Application Publication
(10) Pub. No.: US 2026/0259575 A1
(43) Pub. Date: Sep. 3, 2026

(54) DEVICE FOR REGULATING THE PRESSURE IN A HELIUM TANK OF AN NMR MAGNET, COMPRISING TWO PRESSURE SENSORS

(71) Applicant: Bruker Switzerland AG, Fällanden (CH)

(72) Inventor: Patrick WIKUS, Nürensdorf (CH)

(21) Appl. No.: 19/489,455

(22) PCT Filed: Oct. 24, 2024
(86) PCT No.: PCT/EP2024/080135

§ 371 Date: Dec. 2, 2025

(30) Foreign Application Priority Data
Oct. 31, 2023 (DE) 10 2023 210 824.0

(51) Int. Cl. G05D 16/20; G01R 33/38

(52) U.S. Cl. CPC G05D 16/2013; G01R 33/3804

(57) ABSTRACT

A device (1) for regulating the pressure in a helium tank (2) of an NMR magnet (23), comprising—a first pressure sensor (6) for measuring a first pressure in the helium tank (2), —a control valve (5) for adjusting an outflowing helium gas flow from the helium tank (2), —an electronic closed-loop control device (13) for controlling the control valve (5), wherein the electronic control device (13) is configured to—obtain first pressure values D1 measured by the first pressure sensor (6), —and to adjust a position of the control valve (5) depending on the measured first pressure values D1, wherein the first pressure values D1 are adjusted to a predetermined setpoint value SW, wherein the device (1) further comprises—at least one second pressure sensor (7; 7a) for measuring a second pressure outside the helium tank (2), wherein the electronic closed-loop control device (13) is further configured to—obtain second pressure values D2 measured by the second pressure sensor (7; 7a), —and to ascertain the setpoint value SW depending on the second pressure values D2, and wherein the closed-loop control device (13) is configured to change the setpoint value SW for the pressure in the helium tank (2) in steps as soon as a difference DIF=D1−D2between the measured first pressure value D1 and the measured second pressure value D2 reaches or exceeds predetermined threshold values. The device improves the availability of the NMR magnet.

The invention relates to a device for regulating the pressure in a helium tank of an NMR magnet, comprising
a first pressure sensor for measuring a first pressure in the helium tank,
a control valve for adjusting an outflowing helium gas flow from the helium tank,
an electronic closed-loop control device for controlling the control valve, wherein the electronic closed-loop control device is configured to
obtain first pressure values D1 measured by the first pressure sensor,
and to set a position of the control valve depending on the measured first pressure values D1, wherein the first pressure values D1 are adjusted to a predetermined setpoint value SW.

Such a device has become known from the company publication “EAPD II—Electronic Atmospheric Pressure Device II User Manual Version 002” of the Bruker Corporation, Billerica, MA, USA, dated Jan. 20, 2020.

Superconducting magnets for NMR equipment, such as NMR spectrometers or NMR tomographs, are often cooled with liquid helium. A cryostat comprises a vacuum-insulated tank containing boiling liquid helium and the superconducting magnet.

The pressure in this helium tank should be above the ambient atmospheric pressure to prevent air from being suctioned into the helium tank. Suctioned-in air can lead to the formation of ice due to freezing out of air humidity or other air components, which ice blocks lines or valves and thus endangers operational safety.

The pressure in the helium tank should also be as constant as possible, since pressure fluctuations in the helium tank can lead to artifacts in the NMR measurements, for example via minimal deformations of the helium tank and resulting movements of the superconducting magnet.

In many applications, the helium tank is equipped with a spring-loaded pressure relief valve, which mechanically establishes a fixed pressure difference between the helium tank pressure and atmospheric pressure. Accordingly, the pressure in the helium tank depends on the atmospheric pressure, and the helium tank pressure then fluctuates with the weather-dependent atmospheric pressure. Depending on the weather conditions, this can lead to significant artifacts in the NMR measurements.

With the “EAPD II” from Bruker (see above), the pressure in the helium tank of an NMR magnet is regulated to a predetermined fixed setpoint value using a pressure sensor. To do this, an electronic closed-loop control device controls a control valve through which helium gas can flow out of the helium tank. The recommended setpoint value for the pressure is approximately 15 mbar above the highest atmospheric pressure expected for the location. In most cases, this allows a constant helium tank pressure to be achieved and prevents air from being suctioned in.

However, at many locations atmospheric pressure can fluctuate greatly. For example, during hurricane season in the southern and eastern United States, a weather-related pressure drop of up to approximately 100 mbar can occur. Then the pressure difference between the helium tank pressure and atmospheric pressure can become so large that safety relief valves open to release helium gas, and NMR measurements are no longer possible under stable conditions. If pressure differences are very large, the helium tank's bursting disks may even shatter.

Many cryostats also require occasional refilling with liquid helium. To insert a transfer line, the helium tank must be opened to the atmosphere. If the pressure in the helium tank is suddenly reduced to atmospheric pressure when it is opened, a large amount of cold helium gas is suddenly released, the enthalpy of which cannot be used to capture heat, which is energetically disadvantageous.

From U.S. Pat. No. 3,412,568 A, a pressure regulator is known with which a constant pressure can be set in a cryostat which has a bath of coolant.

From JP 2015 060973 A, it is known to adjust the pressure in a helium tank of a cryostat using an electric heater.

From DE 10 2005 058 650 B3 it has become known to monitor the passability of a tower tube of a cryomagnet in an MRI device using optical means.

US 2009/0280989 A1 describes a control apparatus and an associated method for regulating gas pressure and gas flow in a cryogenic vessel for superconducting magnet coils. Sensors measure the pressure in the container and in the environment. The pressure in the container can be controlled as a function of the ambient pressure. Furthermore, a gradual reduction in pressure in the container is described.

US 2009/0261830 A1 describes a magnetic resonance imaging scanner. The pressure in a cryogenic vessel and in the environment is measured and fed into a processor that controls a pressure regulator so that the largest possible buffer is maintained before pressure relief valves open. This can prevent unnecessary loss of coolant. In one example, the pressure in the cryogenic vessel is maintained at 0.1 psi (approximately 689 Pa) above ambient pressure.

### OBJECT OF THE INVENTION

The object of the invention is to present a device for regulating the pressure in a helium tank with which improved operational reliability and greater user-friendliness can be achieved.

### DESCRIPTION OF THE INVENTION

This object is achieved according to the invention by a device of the type mentioned above, which is characterized in that the device further comprises:
at least one second pressure sensor for measuring a second pressure outside the helium tank, and that the electronic closed-loop control device is further configured
to obtain second pressure values D2 measured by the second pressure sensor,
and to determine the setpoint value SW depending on the second pressure values D2.

The invention provides, in addition to the first pressure sensor, which monitors the first pressure in the helium tank (“helium tank pressure”), the provision of a second pressure sensor which monitors a second pressure outside the helium tank. The second pressure is typically atmospheric pressure or another pressure that depends on atmospheric pressure, for example the pressure in a helium recovery system (which is usually greater than atmospheric pressure by a small pressure difference). The second pressure or the associated second pressure values D2 measured by the second pressure sensor are included in the controlling of the helium tank pressure at least via the setpoint value to be set for the helium tank pressure (i.e., the setpoint value for the first measured pressure values D1). This means that even under fluctuating ambient conditions (detectable by fluctuating second pressure values D2), suitable operating conditions with (at least temporarily) stable helium tank pressure and thus stable measuring conditions with good operational reliability can be achieved. Furthermore, it is possible to modify the helium tank pressure with respect to the second pressure in a desired manner in order to achieve high energy efficiency when using the liquid helium in the system. Finally, dangerous operating conditions (e.g., with a high pressure difference between D1 and D2) can be detected more easily in order to increase operational safety by alerting a user or by taking automatic countermeasures.

The first pressure in the helium tank is set by specifying a setpoint value SW for the pressure in the helium tank in the closed-loop control device, and the measured first pressure value D1 is adjusted to the setpoint value SW by actuation of the control valve by the closed-loop control device. To reduce the pressure in the helium tank, the control valve can then be opened further and/or held in an open position, and to increase the pressure in the helium tank, the control valve can be closed further and/or held in a closed position. Known closed-loop control methods such as P, I, PI, PD or PID regulation can be used.

According to the invention, the setpoint value SW of the pressure in the helium tank is determined in the closed-loop control device taking into account the (instantaneous) measured second pressure value D2, and if necessary also taking into account the (instantaneous) measured first pressure value D1, and taking into account programmed specifications. As part of the adjustment of the first pressure values D1 to the setpoint value SW, the control valve is thus adjusted depending on both the first pressure values D1 and the second pressure values D2, and on the programmed specifications.

If there is no malfunction, with a constant setpoint value or a setpoint value that changes only slowly, for example with a setpoint value change of 10 mbar/h or less, usually 5 mbar/h or less, then the electronic closed-loop control device always keeps the measured first pressure values D1 close to the setpoint value SW, typically with a deviation of a maximum of 1 mbar, preferably maximum 0.5 mbar, particularly preferably maximum 0.25 mbar.

In normal operation for NMR measurements, the setpoint value SW is typically kept constant (at least over the duration of an NMR measurement), and accordingly the pressure in the helium tank is always kept close to the setpoint value by the regulation. In certain operating situations, for example for refilling with liquid helium, certain helium tank pressure curves can be specified by programming, for example a gradual reduction of the helium tank pressure to atmospheric pressure in preparation for opening the helium tank to insert a filler neck, or a gradual increase of the helium tank pressure from atmospheric pressure back to the normal operating pressure; for this purpose, the specified setpoint value is changed accordingly over time by the closed-loop control device. The atmospheric pressure (or a pressure in the helium recovery system) can be determined via the second pressure sensor.

The second pressure sensor or the second pressure values can be used to detect when a change in the setpoint value SW for the helium tank pressure is necessary for safe continued operation, for example due to significant weather changes. Likewise, a desired, energetically favorable course of pressure changes and/or helium gas flows can be established by means of the second pressure sensor or the second pressure values D2.

It should be noted that within the scope of the invention, a pressure or pressure value of interest can be measured directly, or also indirectly via a difference between the pressure or pressure value of interest and a known other pressure or pressure value. For example, second pressure values D2 of the atmospheric pressure can be measured via differential pressure values between the atmosphere and the helium tank if the helium tank pressure is known via the first pressure values D1.

### Embodiments Relating to Sensors

In a preferred embodiment of the device according to the invention, the second pressure is a pressure in the surrounding atmosphere. The pressure of the surrounding atmosphere (also referred to as atmospheric pressure) is particularly relevant for operational safety, in particular because the safety devices of the helium tank (pressure relief valves and bursting disks) react to the pressure difference between the helium tank pressure and atmospheric pressure. In addition, the helium tank pressure can be reduced to atmospheric pressure with good accuracy (via a programmed setpoint value pressure curve) when the helium tank is to be opened (e.g., to prepare for a helium transfer).

Also preferred is an embodiment in which the second pressure is a pressure in a helium recovery system. With a helium recovery system, valuable helium that has evaporated from the helium tank can be captured and stored for reliquefaction, for example. The pressure in the helium recovery system is typically slightly (usually up to 5 mbar) above atmospheric pressure. If a helium recovery system is connected to the helium line leading from the helium tank, the pressure in the helium tank can only be reduced to the pressure in the helium recovery system, which can then be easily adjusted using the second pressure sensor.

In a particularly preferred embodiment, the device further comprises:
a third pressure sensor for measuring a third pressure outside the helium tank,
   wherein the second pressure and the third pressure comprise a pressure in the surrounding atmosphere and a pressure in a helium recovery system. For example, the second pressure sensor measures the pressure of the surrounding atmosphere, and the third pressure sensor measures the pressure in the helium recovery system. By measuring the second and third pressures, malfunctions in the helium recovery system (e.g., a valve that was accidentally closed or a failed compressor) can be easily identified. A typical fault condition (and thus a typical alarm situation) is a pressure in the helium recovery system that is significantly higher (e.g., by more than 5 mbar) than atmospheric pressure.

In a particularly preferred embodiment, the device further comprises:
a flow sensor for measuring a helium flow value of the outflowing helium gas stream from the helium tank. The flow sensor is connected in series with the control valve (typically in the outgoing helium line). The flow sensor opens up expanded monitoring and analysis possibilities. In particular, dangerous icing that blocks the flow of helium gas from the helium tank can be easily detected.

An embodiment is advantageous in which the closed-loop control device comprises a memory device or a connection for a memory device with which sensor values obtained by the closed-loop control device are recorded. By storing the sensor data, the sensor data become available for later analysis. In particular, artifacts in the NMR measurement can be compared with pressure fluctuations in the helium tank and/or outside the helium tank, or the helium consumption of the laboratory or of the NMR magnet can be analyzed. Typically, the storage device also records generated control information, such as the currently valid setpoint value for the helium tank pressure or control commands to the control valve. The storage device usually logs operation for a specified period of time up to the present, for example the last 30 days or the last 180 days.

### Embodiments Relating to The Regulation of the Tank Pressure

A particularly preferred embodiment provides that the control device is designed to change the setpoint value SW for the pressure in the helium tank in steps as soon as a difference DIF=D1-D2 between the measured first pressure value D1 and the measured second pressure value D2 reaches or exceeds predetermined threshold values, in particular wherein the setpoint value SW is increased by one step when the difference DIF becomes less than or equal to an increase threshold value HSW, and the setpoint value SW value is decreased by one step when the difference DIF becomes greater than or equal to a decrease threshold value SSW, with HSW<SSW. This improves the availability of the NMR magnet. By changing the setpoint value in steps, the frequency of changes in the setpoint value (and thus corresponding changes in the pressure in the helium tank) can be kept low, and interruptions in the measurement operation are therefore rarely necessary.

Weather changes cause atmospheric pressure to change, sometimes quite significantly.

If the atmospheric pressure rises sharply and exceeds the currently set setpoint value for the first pressure values or the helium tank pressure, the closed-loop control device would no longer be able to keep the helium tank pressure constant, because the closed-loop control device relies on there being a pressure drop from the helium tank to the helium sink (atmosphere or helium recovery system). In order to continue to ensure a stable pressure in the helium tank, the previous setpoint value is changed by one step to a new, higher setpoint value. While the pressure in the helium tank is being transitioned to the new setpoint value, an NMR measurement would be disturbed. Afterwards, however, a stable pressure can be maintained in the helium tank again.

If the atmospheric pressure drops too far below the current setpoint value for the helium tank pressure, helium would escape from the helium tank via safety devices (pressure relief valves or even bursting disks). In this case, the pressure in the helium tank would no longer be stable, valuable helium would be lost, and repairs to the bursting disks would be necessary. To prevent this, the setpoint value is then changed by one step to a new, lower setpoint value. While the pressure in the helium tank is being transitioned to the new setpoint value, an NMR measurement would be disturbed. Afterwards, however, a stable pressure can be maintained in the helium tank again.

Note that a setpoint value change from a previous setpoint value by one step to the new setpoint value can be achieved by making multiple partial setpoint value changes until the new setpoint value is reached. Likewise, a continuous setpoint value change (e.g., with a linear setpoint value ramp) can be made until the new setpoint value is reached. This allows the pressure change per time in the helium tank to be limited.

A step here refers to the difference between the old setpoint value and the new setpoint value, wherein continuous operation/measurement operation of the helium tank or the NMR magnet was or is provided for the setpoint values. Typically, a step in the range 5-25 mbar is selected, preferably between 8 and 20 mbar, particularly preferably between 10 and 15 mbar. Please note that the steps by which the setpoint value is lowered may be different from the steps by which the setpoint value is raised. It should also be noted that the steps should not be chosen too small, and that an increase threshold and a decrease threshold should not be chosen too close together, in order to limit the frequency of setpoint value changes and to keep the availability of the NMR measurement setup high. The new threshold value is usually changed by the specified step relative to the previous setpoint value; however, it is also possible to set the new threshold relative to a current pressure value (e.g., the current atmospheric pressure).

The increase threshold HSW and the decrease threshold SSW effectively establish an interval for the difference DIF, and the setpoint value SW is adjusted when the difference DIF leaves this interval. As long as DIF remains in the interval, the setpoint value remains constant.

Furthermore, an embodiment is particularly preferred in which the closed-loop control device is designed to transition the setpoint value SW for the pressure in the helium tank to a target value ZW over a predetermined time duration, wherein the target value ZW is dependent on the second pressure value D2,

in particular wherein the time duration can be selected by a user.

As a result, the helium tank pressure can be transitioned to the target value in an energetically efficient manner during the continuous adjustment of the first pressure values D1 to the setpoint value, which changes slowly over time.

This function is particularly advantageous for preparing a helium transfer (refilling liquid helium in the helium tank). Note that helium transfers are usually planned a few days in advance. For the helium transfer, the helium tank must be opened against atmospheric pressure (at a designated access point).

Rapid pressure changes in the helium tank are energetically unfavorable. This is especially true for a rapid pressure drop, such as occurs when a helium tank is suddenly opened whose tank pressure is above atmospheric pressure. The slightly pressurized gas that is present in the helium tank before it is opened then escapes suddenly. The enthalpy of the gas then cannot be used for cooling purposes (e.g., on the tank suspensions). In addition, a sudden increase in the evaporation rate of the boiling helium (which can also trigger a quench) causes a large amount of cold gas to escape, the enthalpy of which also cannot be used.

If the setpoint value is changed depending on the second pressure value, a slow and precise transition of the helium tank pressure to the desired target value dependent on the second pressure (usually this is the atmospheric pressure itself) can be carried out, for example with setpoint value changes of 10 mbar/h or less, or preferably with 5 mbar/h or less. A user can plan the transition time duration so as to reach the desired target value at a specific time, e.g., when the helium transfer is scheduled to begin.

In a preferred further development of this embodiment, it is provided that the target value ZW corresponds to the second pressure value D2 with ZW=D2, or the target value ZW is above the second pressure value D2 by a small pressure addition DA, with ZW=D2+DA and with DA≤3 mbar. With ZW=D2 (where the second pressure is atmospheric pressure), an opening to the atmosphere can occur without a pressure drop. If ZW=D2+DA (where the second pressure is atmospheric pressure), a small overpressure can be maintained in the helium tank for a comparatively long time, even at the end of the transition, which prevents the penetration of contaminants.

A further development is advantageous in which the closed-loop control device is configured to transition the setpoint value SW linearly over time to the target value ZW. This is particularly easy to set up, in particular via software programming.

In an alternative development, the closed-loop control device is designed to change the setpoint value SW non-linearly over time, wherein a helium flow through the control valve is kept approximately constant during the duration of the transition of the setpoint value SW to the target value ZW.

In this case, a transition curve for the setpoint value as a function of time can be calculated/determined in advance so that the approximately constant helium flow is achieved. Alternatively, a flow meter can be provided with which a helium flow value of the outflowing helium gas flow from the helium tank through the control valve is measured, and the closed-loop control device uses the measured helium flow value as a (further) regulating variable.

The pressure and temperature of the boiling helium in the helium tank are related to each other via the vapor pressure curve. However, this only applies to the liquid on the surface, since helium has relatively poor thermal conductivity. Within the liquid helium, a temperature gradient temporarily forms when there are pressure changes.

When the pressure in the helium tank is increased rapidly, the temperature of the liquid helium at the surface rises. The liquid helium below the surface remains colder and only slowly warms up to the surface temperature. During this time, less liquid helium evaporates than would be expected given the heat load on the helium tank, because the helium below the surface absorbs heat with its considerable heat capacity.

When the pressure in the helium tank is reduced rapidly, the temperature of the liquid helium at the surface drops. The liquid helium below the surface remains warmer and cools only slowly to the surface temperature. During this time, more liquid helium evaporates than would be expected given the heat load on the helium tank, because energy must be extracted from the helium below the surface to cool it. The cooling capacity is provided by increased evaporation.

If the helium flow is kept approximately constant, the enthalpy of the cold gas can be used optimally. Typically, the helium flow is kept constant with an accuracy around a target helium flow of +/−20% (or more precise), preferably +/−15% (or more precise), most preferably +/−10% (or more precise).

In a preferred sub-variant of this further development, the closed-loop control device is configured to lower the setpoint value SW more quickly at the beginning of the transition than towards the end of the transition when transitioning the setpoint value SW to the target value ZW. When reducing the pressure in the helium tank, it is advantageous to initially reduce the pressure more quickly (in order to artificially accelerate the initial evaporation) and to reduce the pressure more slowly towards the end of the pressure reduction phase (in order to keep the evaporation rate constant).

### Embodiments Relating to the Alarm System and Alarm Situations

Particularly advantageous is an embodiment in which the device further comprises an alarm device with which an alarm message is automatically triggered in one or more predetermined alarm situations, in particular wherein the alarm device comprises an acoustic signal generator and/or an optical signal generator and/or a radio signal generator and/or a data signal generator. The alarm message can alert a user to dangerous conditions or prompt them to perform further checks of the cryostat system. The alarm message can be used to initiate manual troubleshooting or safety measures, or to trigger and execute troubleshooting or safety measures automatically.

A preferred development of this embodiment is one in which an alarm situation includes the pressure value D1 of the helium tank pressure falling below the pressure value D2 of the atmospheric pressure. If the pressure in the helium tank is below atmospheric pressure, a potentially dangerous situation arises because contaminants can be suctioned into the helium tank through small leaks. This is true in particular for suctioned-in air, whose components (e.g., nitrogen) or whose moisture could freeze out in the helium tank and cause it to ice up. This dangerous situation can arise particularly in systems with active cooling if the cooling is “too strong,” i.e., the active cooling overcompensates for the heat load on the helium tank.

A further development is also advantageous in which an alarm situation includes that the pressure value D1 of the helium tank pressure exceeds a specified helium tank pressure maximum value,

in particular wherein a first alarm situation for D1 comprises that the pressure value D1 of the helium tank pressure exceeds a predetermined first helium tank pressure maximum value EHM, a second alarm situation for D1 comprises that the pressure value D1 of the helium tank pressure exceeds a predetermined second helium tank pressure maximum value ZHM, and ZHM>EHM, and the alarm messages for the first alarm situation for D1 and for the second alarm situation for D1 are different.

A helium tank pressure above a specified maximum pressure can indicate various types of faults, such as a blocked outgoing helium line or a fault causing an increased helium flow rate (see below). If the cryostat and the device (including the control valve, and if applicable the helium recovery system and active cooling) are functioning correctly, an increased helium pressure indicates a malfunction in the superconducting NMR magnet, which leads to an increased evaporation rate and may even trigger a quench. A maximum value can be set so that it is reached shortly before, or alternatively when, the opening pressure of a safety device (pressure relief valve or bursting disk) is reached. If two thresholds (EHM and ZHM) are set up, the first helium tank pressure maximum value (EHM) is typically associated with a triggering of the pressure relief valves (which can be caused for example by an inadvertently closed valve at the magnet outlet), and the second helium tank pressure maximum value (ZHM) is associated with the triggering/destruction of the bursting disks (typically in case of a quench, i.e., a sudden loss of superconductivity in the NMR magnet, “quench alarm”).

A further development is also preferred in which an alarm situation includes a measured helium flow value that exceeds a predetermined maximum helium flow value. An increased helium flow usually indicates a problem in the NMR magnet, such as defective active cooling, a fault in the thermal insulation, a switch opening, or a quenched joint.

A preferred variant of this development is one in which the specified maximum helium flow value depends on current or recently controlled changes in the helium tank pressure,

in particular wherein the maximum helium flow value is higher during and/or shortly after reductions made in the helium tank pressure than when the helium tank pressure is controlled to be constant. When the pressure in the helium tank is reduced, there is a (planned) short-term increase in the helium flow above the normal value. No alarm should be triggered in this case. Due to the poor thermal conductivity of liquid helium mentioned above, the helium flow is also increased for a certain time after a pressure reduction. The short time mentioned above can usually be set at 3 hours or less, usually 2 hours or less. A change in the helium tank pressure is typically controlled by changing the specified setpoint value SW of the helium tank pressure.

A further development is advantageous in which an alarm situation includes that a measured helium flow value falls below a specified minimum helium flow value. If the helium flow is too low, this could indicate a leak in the line between the helium tank and the flow sensor, or a leak at the helium tank, or icing in the helium tank or in the line leading from the helium tank that contains the flow sensor. It is also possible that the NMR magnet is simply not connected to the monitoring device (i.e., the device according to the invention).

A sub-variant of this further development is advantageous wherein the specified minimum helium flow value depends on current or recently controlled changes in the helium tank pressure,

in particular wherein the minimum helium flow value during and/or shortly after increases in the helium tank pressure is lower than when the helium tank pressure is controlled at a constant level. If the pressure in the helium tank is increased, the helium flow will temporarily drop below the normal value. No alarm should be triggered in this case. Due to the poor thermal conductivity of liquid helium mentioned above, the helium flow is also reduced for a certain time after a pressure increase. Please note that the specified minimum helium flow value can even be set to “zero” during and/or shortly after increases made in the helium tank pressure, so that a helium flow value of “zero” also will not trigger the alarm during this time. The short time mentioned above can usually be set at 3 hours or less, usually 2 hours or less.

An advantageous further development is one in which an alarm situation comprises that a measured helium flow value is zero and at the same time a current position of the control valve or a position of the control valve currently controlled by the closed-loop control device is not closed. A drop in the flow to zero indicates dangerous, complete icing of the cryostat or at least of the outgoing helium line. However, the control state should be taken into account: if the control valve is (as planned) completely closed, for example to cause a (deliberate) increase in the pressure in the helium tank, then no alarm should be triggered. Icing of the cryostat (or of the outgoing helium line) is a dangerous situation. The suspension tubes through which helium normally flows are then blocked, and the helium can no longer escape from the helium tank. Since the heat input constantly evaporates helium in the helium tank, pressure builds up in the helium tank until it bursts. For NMR magnets, it is recommended to regularly check whether helium is escaping from the helium tank outlet. Within the scope of the invention, this monitoring can take place continuously and automatically.

A further development is also preferred in which an alarm situation includes that a measured helium flow value is zero and at the same time a pressure value D2 in the helium recovery system has risen to the pressure value D1 in the helium tank. This function can be used to distinguish whether icing is present or whether there is simply a closed valve in the helium recovery system. In both cases, the helium flow drops to zero; in the case of icing, the measured recovery system pressure does not increase; in the case of a closed valve, it does increase. The present alarm situation therefore detects a closed valve in the helium recovery system.

A further development is preferred in which an alarm situation comprises that a difference DHA=DHR-DAT of a measured pressure value DHR in the helium recovery system and a measured pressure value DAT in the surrounding atmosphere exceeds a predetermined threshold value SWW, in particular wherein SWW is selected in a range from 2.5 mbar to 20 mbar. SWW is usually chosen to be greater than 5 mbar. This function detects a malfunction in the helium recovery system, for example a defective compressor.

In an advantageous further development, it is provided that at least some of the alarm situations include a current position of the control valve or a position of the control valve currently controlled by the closed-loop control device. In many cases, this allows dangerous situations or malfunctions to be detected in a targeted manner and more easily distinguished from desired operating states. For example, a vanishing measured helium flow is not critical if a closed control valve is controlled as planned at the same time.

### Method For Pressure Regulation

The present invention also includes a method for regulating the pressure in a helium tank of an NMR magnet,

wherein a first pressure in the helium tank is measured by a first pressure sensor,
wherein a control valve is used to adjust an outflowing helium gas flow from the helium tank,
where an electronic closed-loop control device controls the control valve, and wherein the electronic closed-loop control device
obtains first pressure values D1 measured by the first pressure sensor,
and sets a position of the control valve depending on the measured first pressure values D1, so that the first pressure values D1 are adjusted to a predetermined setpoint value SW,
   characterized in that
   a second pressure outside the helium tank is measured with at least one second pressure sensor,
   and that the electronic closed-loop control device in addition
obtains second pressure values D2 measured by the second pressure sensor,
and ascertains the setpoint SW depending on the measured second pressure values D2,
   in particular wherein the method is carried out using a device according to any of the preceding claims. The method according to the invention for regulating the pressure in the helium tank can achieve improved operational reliability and greater user-friendliness.

In particular, it is possible to change a previous setpoint value for the helium tank pressure (with which a substantially constant helium tank pressure was established) to a modified, new setpoint value if necessary (with which a substantially constant helium tank pressure can then be established again after a short disturbance). The need for change can be detected via the measured second pressure values D2 (and the first pressure values D1). The need for change typically arises when the second pressure values D2 (which represent atmospheric pressure or another pressure dependent on atmospheric pressure, for example in a helium recovery system) indicate that the pressure drop between the helium tank and the subsequent helium sink (further installation downstream of the control valve) required for the regulation is becoming too small, or that a pressure drop between the helium tank and the surrounding atmosphere is becoming so large that safety devices (pressure relief valves or bursting disks) could be triggered. This setpoint value change typically occurs in steps.

It is also possible to slowly transition the helium tank pressure to a target value in a defined manner relative to the second pressure by means of a correspondingly programmed setpoint value change in order to make particularly efficient use of the cooling effect of the gas escaping from the helium tank.

Finally, some dangerous situations can also be detected with the second pressure sensor.

A particularly preferred variant of the method according to the invention provides that the closed-loop control device changes the setpoint value SW for the pressure in the helium tank in steps as soon as a difference DIF=D1−D2 between the measured first pressure value D1 and the measured second pressure value D2 reaches or exceeds predetermined threshold values, in particular wherein the setpoint value SW is increased by one step when the difference DIF becomes less than or equal to an increase threshold value HSW, and the setpoint value is decreased by one step when the difference DIF becomes greater than or equal to a decrease threshold value SSW, with HSW<SSW,

in particular wherein the method is carried out using a device according to claim 7. In this way, a helium tank pressure having good stability can be established between the step-by-step changes of the setpoint value, allowing highly accurate NMR measurements. At the same time, the NMR magnet or its cryostat, including the helium tank, can be operated safely, in particular without control failure or air intake and without triggering safety devices due to excessive pressure differences.

A variant is also preferred that provides:

that the closed-loop control device transitions the setpoint value SW for the pressure in the helium tank to a target value ZW over a specified period of time, where the target value ZW depends on the second pressure value D2, in particular wherein the time period can be selected by a user,
in particular wherein the method is carried out using a device according to claim 8. By means of the target value ZW, which depends on the second pressure values D2, a defined final state with desired properties in relation to the second pressure can be reliably achieved, in particular so that subsequent measures such as opening the helium tank to the atmosphere can be reliably carried out under the desired conditions (desired pressure ratios). In particular, a sharp sudden drop in pressure can be avoided when opening the helium tank to the atmosphere, for example before a helium transfer. In addition, a desired, energetically favorable helium pressure profile can be established via the programmed transition of the setpoint value, thus enabling high energetic efficiency; the transition (change of the setpoint value) is typically continuous and monotone, preferably strictly monotone. The transition is carried out in such a way that the first pressure values D1 always remain close to the setpoint value SW (which can be achieved by a suitable control speed taking into account the interaction of the closed-loop control device and the NMR magnet; see above).

A preferred further development of this variant is one in which the closed-loop control device changes the setpoint value SW non-linearly over time, wherein a helium flow through the control valve is kept approximately constant during the transition of the setpoint value SW to the target value ZW, in particular wherein the method is carried out using a device according to claim 11. Due to the non-linear change of the setpoint value, temperature gradients in the liquid helium that occur during controlled pressure changes in the helium tank can be taken into account, which gradients affect the evaporation rate of helium gas and only decay over a certain period of time. The approximately constant evaporation rate of helium gas (corresponding to a constant helium gas flow) can then be set via the non-linear change of the setpoint value or controlled pressure change in the helium tank, which is particularly favorable energetically.

A variant of the method according to the invention is also preferred which provides

that an alarm device automatically triggers an alarm message in one or more predetermined alarm situations,
in particular wherein the alarm device comprises an acoustic signal generator and/or an optical signal generator and/or a radio signal generator and/or a data signal generator,
and that an alarm situation includes that a measured helium flow value of the outflowing helium gas flow from the helium tank through the control valve is zero and at the same time a current position of the control valve or a position of the control valve currently controlled by the closed-loop control device is not closed,
in particular wherein the method is carried out using a device according to claim 20. A helium flow value of zero, despite the control valve being open, indicates dangerous icing of the helium tank or of the helium line leading from the helium tank and containing the control valve; this condition is detected and reported using the provided function, in particular in order to initiate countermeasures or safety measures. If the closed-loop control device wants to increase the pressure in the helium tank (as planned), for example because the ambient pressure has risen sharply due to weather conditions, the closed-loop control device closes the control valve (as planned) and the helium flow rate drops to zero (as planned) for a period of time, and this then does not trigger an alarm.

### Cryostat Arrangements and NMR Measurement Arrangements

The present invention further includes a cryostat arrangement comprising
a vacuum-insulated helium tank, and
a device according to the invention as described above,
   wherein the first pressure sensor is connected to the helium tank, and the second pressure sensor is connected to a location outside the helium tank, in particular wherein the second pressure sensor is connected to the surrounding atmosphere or to a helium recovery system,
   and wherein the control valve is arranged in a helium line leading from the helium tank. The cryostat arrangement allows the pressure in the helium tank to be controlled with improved operational reliability and high user-friendliness.

An embodiment of the cryostat arrangement according to the invention is preferred in which the cryostat arrangement further comprises a helium recovery system which is connected to the outgoing helium line. This allows the valuable evaporating helium gas to be captured and stored, and, in particular after reliquefaction, it can be reused for further cooling of the NMR magnet.

Furthermore, the present invention also includes an NMR measuring arrangement comprising
a cryostat arrangement according to the invention as described above,
a superconducting NMR magnet in the helium tank of the cryostat arrangement,
an NMR probe head which projects into a room-temperature bore of the vacuum-insulated helium tank, and
an NMR spectrometer control device for controlling NMR measurements with the NMR probe head. The NMR measurement setup enables high-resolution NMR measurements to be performed with high operational reliability and high user-friendliness, in particular while avoiding artifacts caused by pressure fluctuations in the helium tank.

The use of an NMR measuring arrangement according to the invention as described above for carrying out NMR measurements also falls within the scope of the present invention,

wherein the electronic closed-loop control device communicates a status of the regulation of the helium tank pressure to the NMR spectrometer control device,
and wherein during periods of pressure instability in the helium tank, the NMR spectrometer control device pauses the NMR measurements. This procedure avoids artifacts in the NMR measurements. Typical periods of pressure instability during which the NMR measurements are paused are times during which the closed-loop control device triggers a change in the setpoint value and the pressure in the helium tank changes accordingly. In addition, NMR measurements can also be paused during time periods following a change in the setpoint value, during which temperature gradients in the liquid helium are still being equalized (i.e., the helium tank and thus also the pressure in the helium tank are not yet in thermal equilibrium); these latter time periods are usually in the range of up to three hours and can often be recognized by a not-yet-constant helium flow (or a corresponding curve of the controlled or actual position of the control valve). While the helium flow rate is still changing, the temperature distribution in the cryostat can also change, which in turn can cause length changes, for example at suspensions of the helium tank; such length changes can cause artifacts in NMR measurements.

Further advantages of the invention are found in the description and the drawing. Likewise, the features mentioned above and those detailed below can be used according to the invention individually or collectively in any combination. The embodiments shown and described are not to be understood as an exhaustive list, but rather have an exemplary character for the description of the invention.

### DETAILED DESCRIPTION OF THE INVENTION AND DRAWINGS

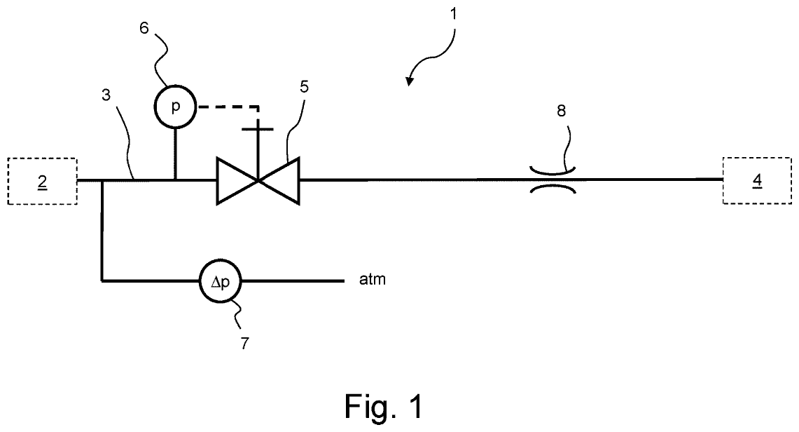

FIG. 1 schematically illustrates a first embodiment of a device according to the invention for regulating the pressure in a helium tank, wherein a second pressure in the surrounding atmosphere is determined by a second pressure sensor;

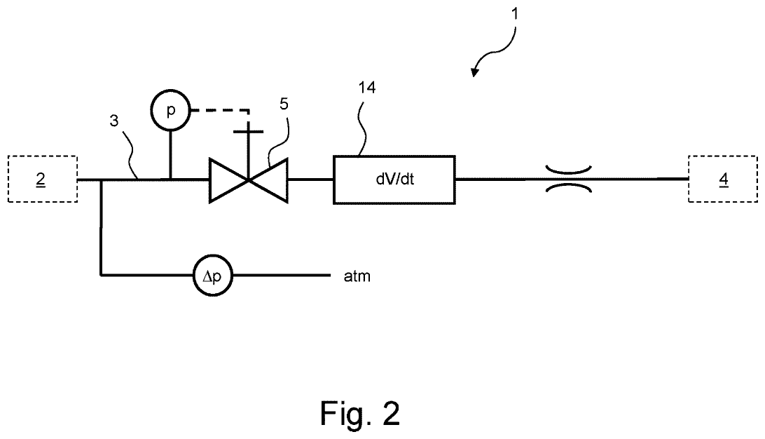

FIG. 2 schematically illustrates a second embodiment of a device according to the invention, wherein a second pressure in the surrounding atmosphere is determined by a second pressure sensor and an outflowing helium gas flow is measured by a flow sensor;

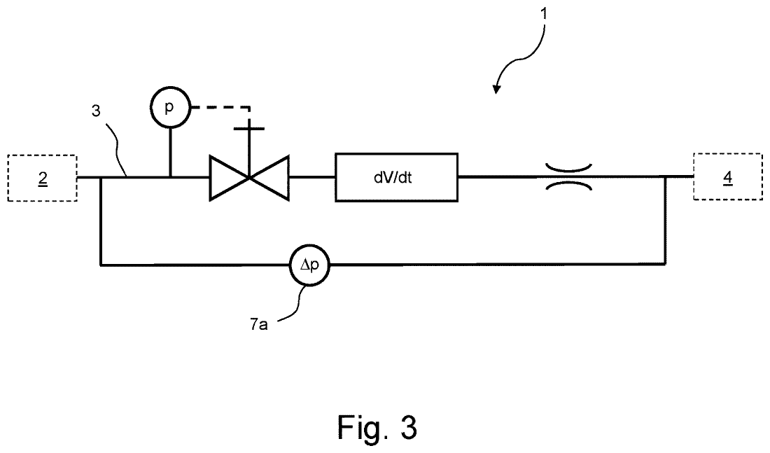

FIG. 3 schematically illustrates a third embodiment of a device according to the invention, wherein a second pressure in a helium recovery system is determined using a second pressure sensor;

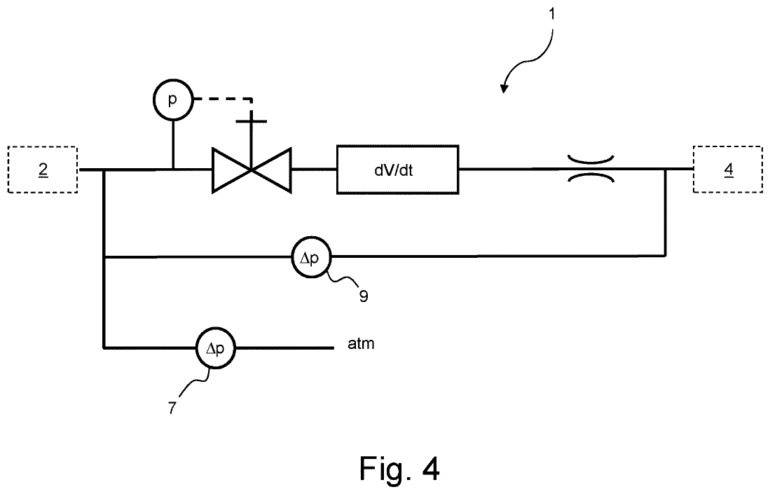

FIG. 4 schematically illustrates a fourth embodiment of a device according to the invention, wherein a second pressure sensor is used to determine a second pressure in a surrounding atmosphere and a third pressure sensor is used to determine a third pressure in a helium recovery system;

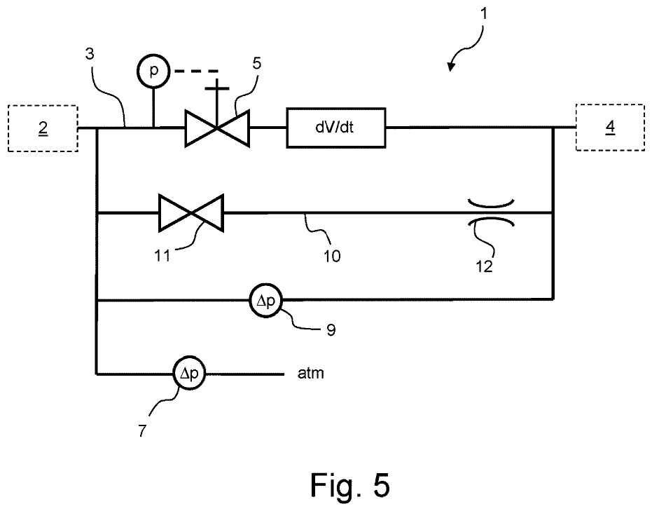

FIG. 5 schematically illustrates a fifth embodiment of a device according to the invention, similar to the embodiment of FIG. 4, wherein an additional line string is provided for a discharge of helium in the event of a power failure;

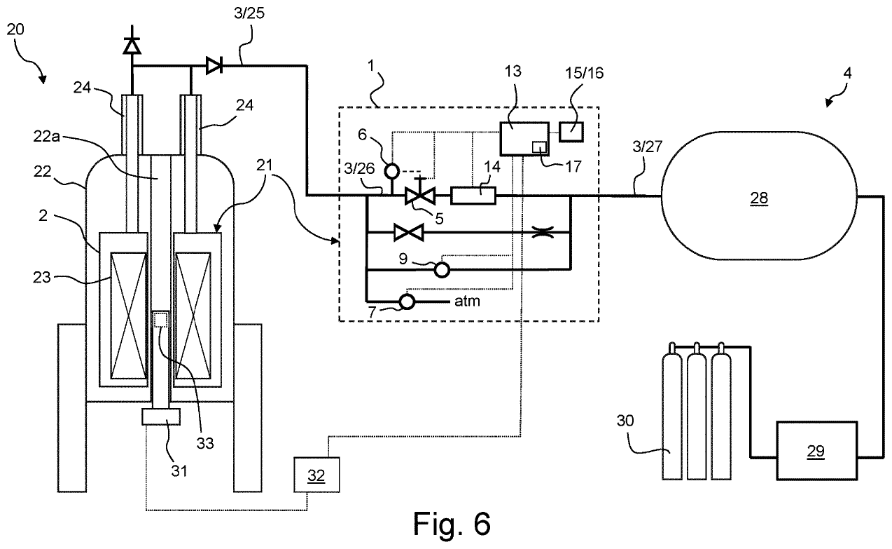

FIG. 6 schematically illustrates an embodiment of an NMR measuring arrangement according to the invention, comprising an embodiment of a cryostat arrangement according to the invention, wherein the cryostat arrangement comprises a device according to the invention, which is designed here according to the embodiment of FIG. 5;

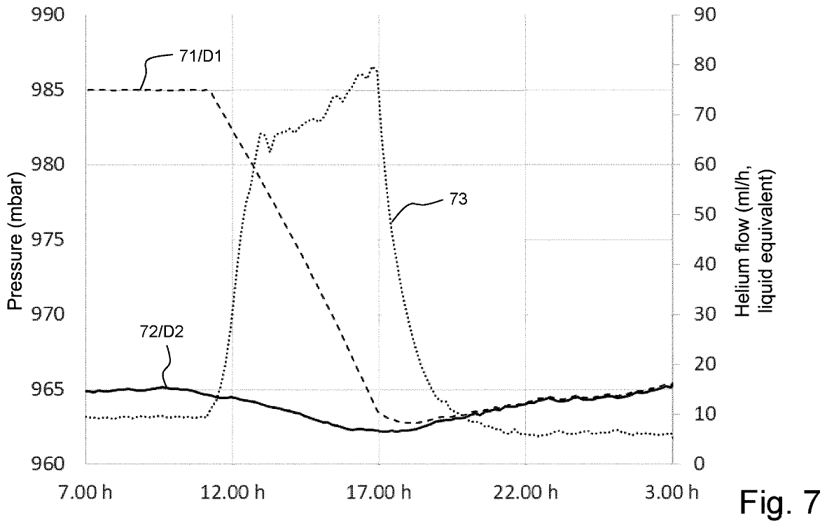

FIG. 7 illustrates, in a schematic diagram, a first variant of a method according to the invention for regulating the pressure in a helium tank, wherein the setpoint value for the pressure in the helium tank is reduced along a linear ramp to a target value corresponding to the measured atmospheric pressure;

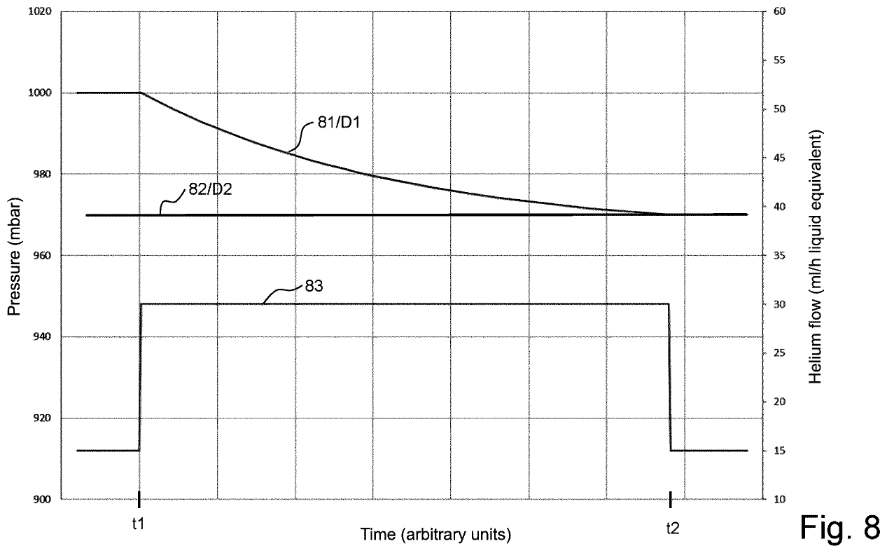

FIG. 8 illustrates, in a schematic diagram, a second variant of a method according to the invention for regulating the pressure in a helium tank, wherein the setpoint value for the pressure in the helium tank is reduced along a non-linear ramp to a target value corresponding to the measured atmospheric pressure;

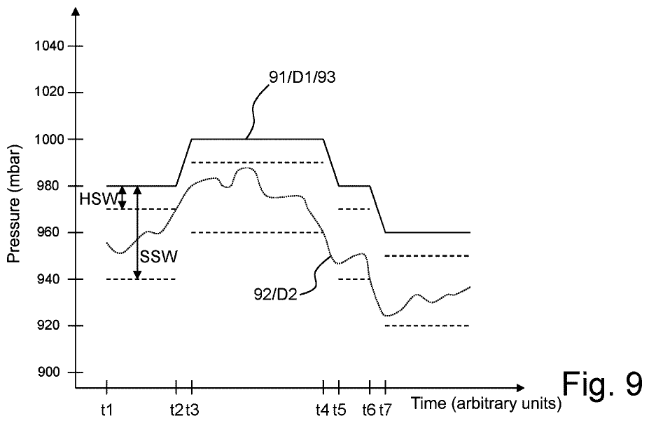

FIG. 9 illustrates, in a schematic diagram, a third variant of a method for regulating the pressure in a helium tank, wherein the setpoint value for the pressure in the helium tank is changed in steps;

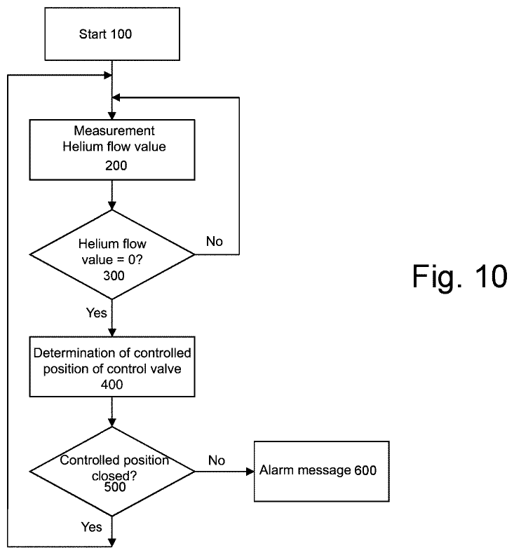

FIG. 10 schematically illustrates a test sequence for detecting icing of the cryostat and a corresponding output of an alarm message, wherein the test sequence can be applied in a method according to the invention for regulating the pressure in a helium tank.

FIG. 1 schematically shows a first embodiment of a device 1 according to the invention for regulating the pressure in a helium tank 2 of an NMR magnet.

A helium line 3 leading from the helium tank 2 connects the helium tank 2 here with a helium recovery system 4. An automatically actuated control valve 5 is integrated into the helium line 3. For its actuation, the control valve 5 has for example an electric motor (not shown in detail). In the helium line 3 upstream of the control valve 5, a first pressure sensor 6 is also arranged with which the pressure in the helium tank 2 can be measured.

First pressure values D1 determined by the first pressure sensor 6 are read out by an electronic closed-loop control device (not shown in detail here, but see FIG. 6) and are compared with a predetermined setpoint value SW for the helium tank pressure. The closed-loop control device controls the control valve 5 so that the helium tank pressure or the measured first pressure values D1 are adjusted to the setpoint value SW. If the control is working correctly (i.e., there is no fault/defect), the first pressure values D1 always remain close to the setpoint value SW, typically with a deviation of 1 mbar or less.

Furthermore, a second pressure sensor 7 is provided which measures a pressure difference between the pressure in the helium tank and the pressure of the surrounding atmosphere atm. As a result (and with knowledge of the first pressure values D1), a second pressure is indirectly measured outside the helium tank 2, in this case the atmospheric pressure. The corresponding second pressure values D2 of the atmospheric pressure are evaluated by the closed-loop control device, wherein the closed-loop control device uses the second pressure values D2 to determine the predetermined setpoint value SW, which is used for adjusting the control valve 5.

Note that atmospheric pressure depends on the weather and changes over time, sometimes changing strongly depending on the weather conditions.

During normal operation, the setpoint value SW is held constant as long as the measured second pressure values D2 (and possibly also the first pressure values D1) do not indicate a need to change the setpoint value SW; the criteria for determining when a change to the setpoint value SW is necessary and how this change should be made are defined in the programming of the closed-loop control device. Typically, the setpoint value SW is held constant as long as the second pressure values D2 are within a specified interval with respect to the previous setpoint value SW (or with respect to the first pressure value D1 in each case); when the second pressure values D2 leave the specified interval, a stepwise change of the setpoint value SW occurs (see FIG. 9 for more on this).

In addition, it is possible to program a gradual transition of the helium tank pressure or the setpoint value SW to a target value ZW in the closed-loop control device, wherein the target value ZW is ascertained using the second pressure values D2. For example, the second pressure value D2 in each case, here the atmospheric pressure, can be selected as the target value in order to prepare an opening of the helium tank to the atmosphere in order to refill liquid helium in the helium tank 2 (for more on this, see FIG. 7 and FIG. 8).

In the embodiment of FIG. 1, the control valve 5 is designed so that in the event of a power failure the control valve 5 assumes a fully open position. This ensures that dangerous pressure cannot build up in helium tank 2. The helium gas flow flowing out when the control valve 5 is fully open is limited by a throttle 8 in the helium line 3.

FIG. 2 schematically shows a second embodiment of a device 1 according to the invention for regulating the pressure in a helium tank 2. The embodiment of FIG. 2 accordingly largely corresponds to the embodiment of FIG. 1, so that only the essential differences are explained.

In the device 1 of FIG. 2, the helium line 3 further contains a flow sensor 14 with which the helium gas flow currently flowing through the helium line 3 or the control valve 5 is measured. The corresponding helium flow values are read out by the closed-loop control device. The flow sensor 14 is arranged here, in the flow direction, behind the control valve 5 in the helium line 3.

The closed-loop control device can use the helium flow values to check the correct operating state of the device 1 or the entire associated cryostat (see also FIG. 6). The closed-loop control device typically checks various alarm situations. In particular, it can be checked whether there is dangerous icing of the cryostat (see also FIG. 10).

The flow sensor 14 typically determines the instantaneous volume of helium gas flowing through per unit time (dV/dt); a turbine wheel flow meter can be used for this purpose. However, it is also possible to determine the instantaneous mass of helium gas flowing through per unit of time (dm/dt) using a flow sensor, for example a Coriolis mass flow meter or a thermal mass flow meter.

FIG. 3 shows a third embodiment of a device according to the invention, which largely corresponds to the embodiment of FIG. 2. Therefore, only the essential differences are explained.

In the embodiment of FIG. 3, a second pressure sensor 7a is provided which measures a pressure difference between the pressure in the helium tank 2 and the pressure in the helium recovery system 4 (here at its inlet). As a result (and with knowledge of the first pressure values D1), a second pressure outside the helium tank 2 is indirectly measured, here the pressure in the helium recovery system 4. The corresponding second pressure values D2 of the pressure in the helium recovery system 4 are evaluated by the closed-loop control device, wherein the second pressure values D2 are used to ascertain the predetermined setpoint value SW, which is used for the adjustment of the control valve 5.

Note that the pressure in the helium recovery system 4 is typically slightly above atmospheric pressure, usually by up to 5 mbar.

FIG. 4 shows a fourth embodiment of a device according to the invention, which largely corresponds to the embodiment of FIG. 2. Therefore, only the essential differences are explained.

In this embodiment, a second pressure sensor 7 is provided, which measures the differential pressure between the helium tank 2 and the surrounding atmosphere atm, whereby the atmospheric pressure is measured indirectly (with the first pressure values D1). Associated second pressure values D2 (also designated DAT) of the measured atmospheric pressure are passed on to the closed-loop control device. On the other hand, a third pressure sensor 9 is provided here which measures the pressure difference between the helium tank 2 and the helium recovery system 4 (here at its inlet), whereby the pressure in the helium recovery system 4 is indirectly measured (with the first pressure values D1). Associated third pressure values D3 (also designated DHR) of the pressure in the helium recovery system 4 are also passed to the closed-loop control device.

The second pressure values D2 can be used to determine the specified setpoint value. The first pressure values D1, the second pressure values D2, the third pressure values D3 and the helium flow values are used to check various alarm conditions, with which the proper operation of the device 1 or the entire cryostat can be monitored by means of the electronic closed-loop control device. In particular, malfunctions in the helium recovery system 4 can be detected by comparing the second pressure values D2 (=DAT) and the third pressure values D3 (=DHR). For example, a failed compressor in the helium recovery system 4 results in the pressure DHR exceeding the pressure DAT by more than a predetermined threshold value SWW, where SWW is selected, for example, to be 10 mbar.

FIG. 5 shows a fifth embodiment of a device according to the invention, which largely corresponds to the embodiment of FIG. 4. Therefore, only the essential differences are explained.

In the embodiment of FIG. 5, an additional line 10 is provided, which runs parallel to the helium line 3 from the helium tank 2 to the helium recovery system 4. The additional line 10 contains a shut-off valve 11 and a throttle 12. During normal operation, the shut-off valve 11 is kept closed by an electrical actuator (not shown) so that the additional line 10 is blocked and helium gas flow can only occur through the helium line 3.

The control valve 5 in the helium line 3 is designed in such a way that it assumes a closed position in the event of a power failure; the helium line 3 is then blocked. In contrast, the shut-off valve 11 is designed to assume an open position in the event of a power failure (the electrical actuator can no longer keep the shut-off valve 11 closed in the event of a power failure; instead, the shut-off valve 11 then opens, typically through spring force). In the event of a power failure, helium gas can flow from the helium tank 2 to the helium recovery system 4 through the additional line 10; the helium gas flow is limited by the throttle 12 in the additional line 10. This prevents a dangerous build-up of pressure in the helium tank 2 in the event of a power failure.

FIG. 6 illustrates by way of example an embodiment of an NMR measuring device 20 according to the invention, in which an exemplary embodiment of a cryostat arrangement 21 according to the invention is contained.

The cryostat arrangement 21 comprises, on the one hand, an evacuated container 22 (also called a vacuum tank) in which a helium tank 2 is arranged; the helium tank 2 is thus vacuum-insulated. The helium tank 2 is partially filled with liquid helium and partially filled with gaseous helium (helium not shown in detail), and also contains a superconducting NMR magnet 23 which is cooled by the liquid helium.

On the other hand, the cryostat arrangement 21 comprises a device 1 for regulating the pressure in the helium tank 2, which is designed substantially as shown in FIG. 5. Also shown here is the electronic closed-loop control device 13, which receives measured values from the pressure sensors 6, 7, 9 and from the flow meter 14, and can also control and read out the position of the control valve 5. The closed-loop control device also comprises a storage device 17 in which obtained measurement data and generated control data, here from the last 30 days, are stored. The electronic closed-loop control device 13 is also connected to an alarm device 15, which comprises a (here) acoustic and optical signal generator 16, with which detected alarm situations are made known.

The helium tank 2 is connected via neck tubes 24 and a front portion 25 of the outgoing helium line 3 to the device 1, more precisely to a middle portion 26 of the helium line 3, which runs in the device 1. Accordingly, the first pressure sensor 6 can measure the pressure in the helium tank 2.

The cryostat arrangement 21 here also comprises the helium recovery system 4, which is connected to a rear portion 27 of the helium line 3. The helium recovery system 4 here comprises a balloon storage device 28 in which helium gas is initially collected. The balloon storage device 28 is exposed to atmospheric pressure from the outside and, during operation, inflates slightly against the atmospheric pressure due to inflowing helium, so that the pressure inside the balloon storage device 28 is slightly above atmospheric pressure. A compressor 29 is connected to an outlet of the balloon storage 28, which compressor can compress helium from the balloon storage device (for example to a pressure of up to 200 bar) and stores the compressed helium gas in compressed gas cylinders 30.

In addition to the cryostat arrangement 21, the NMR measuring system 20 further comprises the superconducting NMR magnet 23 in the helium tank 2, and further an NMR probe head 31 which projects into a room-temperature bore 22a of the vacuum tank 22 or of the vacuum-insulated helium tank 2. In addition, the NMR measuring arrangement 20 also includes an NMR spectrometer control device 32 with which NMR measurements with the NMR probe head 31 can be controlled. NMR measurements can be performed on samples placed in a sample volume 33 in the region of the outer end of the NMR probe head 31, typically with the samples being introduced from above into the room-temperature bore 22 via a sample introduction system (sample introduction system not shown). The NMR spectrometer control device 32 also receives information about the status of the helium tank pressure regulation from the electronic closed-loop control device 13.

FIG. 7 illustrates, in an example, the course of a first variant of a method according to the invention for controlling the pressure in a helium tank, using a diagram. At the right, time is plotted using example clock times. The measured pressure is plotted at the top (for the dashed curve 71, the pressure in the helium tank, i.e., the first pressure values D1, and for the solid curve 72 the measured atmospheric pressure, i.e., the second pressure values D2) and the measured helium flow (helium flow values, dotted curve 73). In the variant, an opening of the helium tank against atmospheric pressure for refilling with liquid helium is to be prepared, and the helium tank pressure is to be transitioned/reduced accordingly. Note that FIG. 7 was obtained with experimentally obtained measured values.

### BRIEF OVERVIEW

Before the reduction begins, in the time period between 7:00 and approximately 11:00, normal operation of the helium tank continues, during which NMR measurements, for example, can be carried out. The setpoint value for the helium tank pressure is set to 985 mbar, and the measured helium tank pressure values of curve 71 are very precisely at 985 mbar. The measured atmospheric pressure of curve 72 fluctuates slightly around a value of, here, approximately 965 mbar. The slight overpressure in the helium tank prevents contaminants from being suctioned in (in particular humid air). During this normal operation, a comparatively small, approximately constant flow of helium gas of approximately 10 ml/h liquid equivalent flows through the control valve; the cooling capacity associated with the evaporation of this amount of helium compensates for the heat load on the cryostat.

At 11:00 h, the pressure reduction in the helium tank begins. The reduction is programmed in such a way that the setpoint value of the helium tank pressure is reduced at a constant reduction rate (i.e., with a linear ramp) of approximately 3.66 mbar/h from the previous setpoint value of 985 mbar to atmospheric pressure as the target value. The reduction speed and the closed-control loop as a whole are set up in such a way that the helium tank pressure or the first pressure values D1 of the curve 71 can follow the linearly decreasing setpoint value quite accurately (promptly). In order to reduce the helium tank pressure according to the programmed setpoint value curve, the electronic closed-loop control device opens the control valve significantly wider than in the previous normal operation, and the helium flow increases significantly, here up to 80 ml/h liquid equivalent. Note that during the ongoing reduction, the atmospheric pressure decreases slightly, as can be seen from curve 72, here to about 962 mbar at around 17:00 h.

Shortly after 17:00 h, the programmed setpoint value reaches atmospheric pressure and the closed-loop control device moves the control valve to a less open position. However, due to temperature gradients within the liquid helium in the helium tank, the evaporation rate remains elevated for some time, and in order to keep the pressure in the helium tank approximately at the setpoint value (which corresponds substantially to atmospheric pressure starting shortly after 17:00 h), a corresponding outflow of helium gas must be allowed via the control valve by a corresponding valve position. At approximately 20:00 h, the temperature gradients in the helium tank have equalized, and the helium flow again reaches a constant, low value of just under 10 ml/h liquid equivalent.

In this state, the helium tank can be opened to the atmosphere without causing an energetically unfavorable, sudden evaporation of a large amount of liquid helium.

### Detailed Explanation

A significant advantage resulting from the use of two pressure sensors according to the invention is that the pressure in the helium tank (first pressure) can be automatically adjusted to the second pressure (e.g., atmospheric pressure or the pressure in the helium recovery system) in a time interval determinable by the user. This is desirable, for example, before a helium transfer. For a helium transfer, an opening that provides access to the helium tank must be opened in order to insert the transfer line. During this, helium gas escapes from the helium tank, typically so quickly that the helium tank relaxes to atmospheric pressure. The rapid pressure change poses a certain risk to the magnet (there is a possibility that the magnet will quench), and secondly it is thermodynamically inefficient because the enthalpy of the cold helium gas remains unused during the rapid escape.

Within the scope of the invention, the pressure in the helium tank can be reduced slowly and precisely; in particular, the pressure reduction can begin the day before the planned helium transfer. This is energetically more beneficial than a “sudden” relaxation. An example of a pressure reduction over a specified period of 6 hours is shown in FIG. 7. The solid line (curve 72) shows the atmospheric pressure, the dashed line (curve 71) shows the pressure in the helium tank, and the dotted line (curve 73) shows the helium flow.

It is clearly visible from curve 73 that the helium flow initially increases only slowly after the pressure reduction begins at around 11:00 h, then continues to increase during the further pressure reduction (although the pressure reduction is linear), and then remains elevated for several hours after the pressure reduction is completed at around 17:00 h.

The pressure and temperature of the boiling helium in the helium tank are related to each other via the vapor pressure curve. However, this only applies to the liquid on the surface, since helium has relatively poor thermal conductivity. Within the liquid helium, a temperature gradient temporarily forms when there are pressure changes.

When the pressure is rapidly reduced in the helium tank, as in the illustrated example above, the temperature of the liquid helium at the surface drops, and the liquid helium below the surface remains warmer and cools only slowly to the surface temperature. During this time, more liquid helium evaporates than would be expected given the heat load on the helium tank, because energy must be extracted from the helium below the surface to cool it. The cooling capacity is provided by increased evaporation. After the pressure reduction has been completed, the helium below the surface is usually not yet in thermal equilibrium with the surface, and the evaporation rate (or the measured helium flow) remains elevated for some time even after the pressure reduction has been completed.

This effect is strongly time-dependent-the faster the pressure reduction is carried out, the more pronounced the effect is, since there is less time to approach thermal equilibrium within the liquid volume.

It is particularly advantageous to keep the helium flow as constant as possible during the pressure reduction, as this allows the enthalpy of the cold gas to be used optimally. When reducing the pressure in the helium tank, it is therefore advantageous to initially reduce the pressure more quickly (in order to artificially accelerate the initial evaporation) and to reduce the pressure more slowly towards the end of the pressure reduction phase (in order to keep the evaporation rate constant). This can be achieved with the device according to the invention. FIG. 8 illustrates, relating to this, a second variant of a method according to the invention for pressure regulation in a helium tank.

The diagram in FIG. 8 plots the time (in arbitrary units) at the right, and the pressure (in curve 81 the first pressure/first pressure values D1 in the helium tank, and in curve 82 the atmospheric pressure/second pressure values D2) and the helium flow through the control valve (curve 83, helium flow values) at the top.

Before time t1, normal operation still prevails, and the setpoint value of the helium tank pressure is 1000 mbar, and the first pressure values D1 of the curve 81 are accordingly constantly at this setpoint value. The atmospheric pressure of the curve 82 is 970 mbar; the atmospheric pressure remains constant throughout the entire observation period. The helium flow is initially at a low 15 ml/h liquid equivalent.

Starting at time t1 and continuing through the reduction period until time t2, the setpoint value of the helium tank pressure is reduced to atmospheric pressure according to a non-linear ramp; the first pressure values D1 of the curve 81 promptly follow the setpoint value according to the adjustment. At the beginning of the reduction period, the pressure reduction per unit of time is still relatively large and then continues to decrease until the end of the reduction period. By appropriately selecting the course of the setpoint value change, it can be achieved that the helium flow remains approximately constant over the entire reduction period from t1 to t2, in the example shown at approximately 30 ml/h liquid equivalent as seen in curve 83. At time t2, the control valve can then be closed again far enough that a low helium flow of 15 ml/h liquid equivalent is again established.

The procedure according to FIG. 7, with gradual linear setpoint value reduction, already achieves a significant energetic improvement compared to a sudden pressure reduction when opening the helium tank, and with the procedure according to FIG. 8 with non-linear setpoint value reduction a further increase in energetic efficiency can be achieved.

FIG. 9 shows a third variant of the method according to the invention for regulating the pressure in a helium tank. The diagram plots the time (in arbitrary units) at the right and the pressure at top (with curve 91 representing the first pressure/helium tank pressure with first pressure values D1, which corresponds with good accuracy to the curve 93 of the setpoint value pressure in the helium tank, and further with curve 92 representing the second pressure/atmospheric pressure with second pressure values D2).

In the third variant, the helium tank pressure is stabilized for normal operation of the NMR magnet in order to minimize measurement artifacts in NMR measurements and at the same time to take weather conditions into account, thus achieving a high level of operational reliability. The electronic closed-loop control device sets the setpoint value for the helium tank pressure and, in particular, also makes changes to the setpoint value for the helium tank pressure, evaluating the second pressure, in this case the atmospheric pressure.

During normal operation, the helium tank pressure should remain constant during NMR measurements, as pressure fluctuations can trigger dimensional changes in the measurement system, which can for example change the sample position relative to the magnet or distort the magnet itself. Accordingly, the setpoint value of the helium tank pressure (see curve 93) is kept at a constant value most of the time, here in the time periods from t1 to t2, from t3 to t4, from t5 to t6, and from t7 onward; the helium tank pressure (see curve 91) follows the setpoint value quite precisely/promptly. During these time periods, NMR measurements can be performed under stable measurement conditions.

Furthermore, the helium tank pressure (see curve 91) should always be significantly higher than atmospheric pressure (see curve 92) to prevent impurities (such as moist air) from being suctioned into the helium tank. As the atmospheric pressure increases, it comes closer to the helium tank pressure or setpoint value. In the illustrated example, the current difference DIF between the helium tank pressure (with pressure values D1) and the atmospheric pressure (with pressure values D2) is checked and compared with an increase threshold value HSW. DIF=D1-D2 checks whether DIF≤HSW has become true. If so, the setpoint value (see curve 93) is increased by one step, where one step here is 20 mbar. In the present case, DIF becomes smaller than HSW at time t2, and the previous setpoint value of 980 mbar before t2 is increased to a new setpoint value of 1000 mbar starting from t3. Between t2 and t3, the setpoint value (curve 93) is raised with a linear increase curve so that the helium tank pressure (curve 91) can follow this change well/promptly. Starting from time t3, the setpoint value and the helium tank pressure then remain constant again, here until t4, despite various fluctuations in the curve 92.

Furthermore, it should be ensured that the overpressure in the helium tank does not become too great relative to the surrounding atmosphere. The helium tank must not be allowed explode due to overpressure under any circumstances. To ensure this, the helium tank has pressure relief valves that open and release helium when a certain difference is reached, and as a further safety step, there are bursting disks through which (after the disks burst) large quantities of helium gas can flow out from the helium tank, in particular in the event of a quench. However, the triggering of the safety devices should be reserved for unforeseen emergencies. In the illustrated example, it is therefore still provided to check the current difference DIF between the helium tank pressure (with pressure values D1) and the atmospheric pressure (with pressure values D2) and to compare it with an increase threshold value SSW. DIF=D1-D2 checks whether DIF>SSW has become true. If yes, the setpoint value (see curve 93) is reduced by one step, where one step here is also 20 mbar. In the present case, DIF becomes greater than SSW at t4, and the previous setpoint value of 1000 mbar before t4 is reduced to a new setpoint value of 980 mbar starting from t5. Between t4 and t5, the setpoint value (curve 93) is reduced with a linear reduction curve so that the helium tank pressure (curve 91) can follow this change well/promptly. Starting from time t5, the setpoint value and the helium tank pressure then remain constant again, here until t6. Furthermore, DIF becomes larger than SSW again at t6, and the previous setpoint value of 980 mbar before t4 is reduced to a new setpoint value of 960 mbar starting from t7. Between t6 and t7, the setpoint value (curve 93) is reduced with a linear reduction curve so that the helium tank pressure (curve 91) can follow this change well/promptly. Starting from time t7, the setpoint value and the helium tank pressure then remain constant again.

During the times of setpoint value change, i.e., from t2 to t3, from t4 to t5, and from t6 to t7, no NMR measurements are carried out due to unstable pressure conditions (changing pressure) in the helium tank. The electronic closed-loop control device reports the ongoing setpoint value change or pressure instability to the NMR spectrometer control device, which sets up measurement pauses for these times.

FIG. 10 illustrates, in a schematic flow diagram, an exemplary monitoring of the correct operation of a device according to the invention for regulating the pressure in a helium tank or an associated NMR measuring arrangement based on an alarm situation for monitoring icing of the cryostat. Other alarm situations can be monitored in an analogous manner. The device is designed for example as shown in FIG. 5, or the NMR measuring arrangement as shown in FIG. 6.

After the monitoring has started 100, the current helium flow value is measured 200 with the flow meter. The read-out helium flow value is then compared 300 with a helium flow value of “zero.” If the measured helium flow value is greater than zero, the helium flow value 200 is measured again (as part of continuous monitoring), and so on.

If the measured helium flow value is equal to zero, the position of the control valve 400 controlled by the closed-loop control device is determined. The controlled position is then compared 500 with a (fully) closed position. If the controlled position of the control valve is a (fully) closed position, it can be assumed that, according to the programming of the closed-loop control device, the pressure in the helium tank is currently to be increased, and therefore the control valve is scheduled to be closed and the helium flow is scheduled to be blocked; the monitoring is then continued (as part of the continuous monitoring) with a next measurement of the helium flow value 200.

If the controlled position of the control valve is not a (fully) closed position, it must be assumed that there is an undesirable and dangerous blockage of the helium flow due to icing of the cryostat or of the helium line leading from the helium tank. An alarm message 600 is then issued accordingly. Based on the alarm message 600, manual or automatic countermeasures or safety measures can then be taken.

### LIST OF REFERENCE SIGNS

1 Device
2 Helium tank
3 Helium line leading from the helium tank
4 Helium recovery system
5 Control valve
6 First pressure sensor (for helium tank pressure)
7 Second pressure sensor (here: differential pressure gauge for atmospheric pressure)
7a Second pressure sensor (here: differential pressure gauge for pressure in the helium regeneration system)
8 Throttle (in helium line 3)
9 Third pressure sensor (here: differential pressure gauge for pressure in the helium regeneration system)
10 Additional cable harness
11 Shut-off valve
12 Throttle (in the further wiring harness 10)
13 Electronic closed-loop control device
14 Flow sensor
15 Alarm device
16 Acoustic and optical signaling devices
17 Storage device
20 NMR measuring arrangement
21 Cryostat arrangement
22 Evacuated container/vacuum tank
22a Room-temperature bore
23 Superconducting NMR magnet
24 Neck tubes
25 Front portion of the helium line
26 Middle portion of the helium line in the device
27 Rear portion of the helium line
28 Balloon storage
29 Compressor
30 Pressurized gas containers
31 NMR probe head
32 NMR spectrometer control device
33 Sample volumes
71 Curve first pressure values (helium tank pressure)
72 Curve second pressure values (atmospheric pressure)
73 Curve helium flow values
81 Curve first pressure values (helium tank pressure)
82 Curve second pressure values (atmospheric pressure)
83 Curve helium flow values
91 Curve first pressure values (helium tank pressure)
92 Curve second pressure values (atmospheric pressure)
93 Curve setpoint value for helium tank pressure
100 Start
200 Measurement of helium flow value
300 Comparison of helium flow value with zero
400 Determination of the controlled position of the control valve
500 Comparison of the controlled position of the control valve with the (fully) closed position
600 Alarm message
atm Surrounding atmosphere
D1 First pressure values (helium tank pressure)
D2 Second pressure values (here usually atmospheric pressure)
D3 Third pressure values
DIF Difference between first pressure value and second pressure value, DIF=D1−D2
SW Increase threshold value
SSW Decrease threshold value
t1-t7 Times

1-34. (canceled)

35. A device for regulating the pressure in a helium tank of an NMR magnet, comprising:
a first pressure sensor for measuring a first pressure in the helium tank;
at least one second pressure sensor for measuring a second pressure outside the helium tank;
a control valve for adjusting an outflowing helium gas flow from the helium tank; and
an electronic closed-loop control device that controls the control valve and is configured to:
obtain first pressure values D1 measured by the first pressure sensor;
adjust a position of the control valve depending on the measured first pressure values D1, wherein the first pressure values D1 are adjusted to a predetermined setpoint value SW; and
obtain second pressure values D2 measured by the second pressure sensor,
wherein the electronic closed-loop control device is further configured, in a normal operation for NMR measurements:
to determine the setpoint SW depending on the first pressure values D1 and the second pressure values D2; and
to change the setpoint value SW for the pressure in the helium tank in steps as soon as a difference DIF=D1−D2 between the measured first pressure value D1 and the measured second pressure value D2 reaches or exceeds predetermined threshold values, wherein the setpoint value SW is raised by one step when the difference DIF becomes less than or equal to an increase threshold value HSW, and the setpoint value SW is lowered by one step when the difference DIF becomes greater than or equal to a decrease threshold value SSW, with HSW<SSW, a value of said one step being selected from the range 5-25 mbar.

36. The device according to claim 35, wherein the second pressure is a pressure in the surrounding atmosphere.

37. The device according to claim 35, wherein the second pressure is a pressure in a helium recovery system.

38. The device according to claim 35, further comprising a third pressure sensor for measuring a third pressure outside the helium tank, wherein the second pressure and the third pressure comprise a pressure in the ambient atmosphere and a pressure in a helium recovery system.

39. The device according to claim 35, further comprising a flow sensor for measuring a helium flow value of the outflowing helium gas flow from the helium tank.

40. The device according to claim 35, wherein the closed-loop control device comprises a memory device or a connection for a memory device with which sensor values obtained by the closed-loop control device are recorded.

41. The device according to claim 35, wherein the closed-loop control device is configured, in a special operation for refilling of liquid helium, to transfer the setpoint value SW for the pressure in the helium tank to a target value ZW over a predetermined period of time, wherein the target value ZW is dependent on the second pressure value D2.

42. The device according to claim 41, wherein the target value ZW corresponds to the second pressure value D2 with ZW=D2, or the target value ZW is a small pressure increase DA above the second pressure value D2, with ZW=D2+DA and with DA≤3 mbar.

43. The device according to claim 41, wherein the closed-loop control device is configured, in the special operation for refilling of liquid helium, to transition the setpoint value SW linearly over time to the target value ZW.

44. The device according to claim 41, wherein the closed-loop control device is designed, in the special operation for refilling liquid helium, to change the setpoint value SW non-linearly over time, wherein a helium flow through the control valve is kept approximately constant during the duration of the transition of the setpoint value SW to the target value ZW.

45. The device according to claim 44, wherein the closed-loop control device is configured, in the special operation for refilling of liquid helium, to lower the setpoint value SW more quickly at the beginning of the transition than towards the end of the transition when transitioning the setpoint value SW to the target value ZW.

46. The device according to claim 35, further comprising an alarm device with which an alarm message is automatically triggered in one or more predetermined alarm situations.

47. The device according to claim 46, wherein an alarm situation comprises that the pressure value D1 of the helium tank pressure falls below the pressure value D2, which is a pressure in the surrounding atmosphere.

48. The device according to claim 46, wherein a first alarm situation for D1 comprises that the pressure value D1 of the helium tank pressure exceeds a predetermined first helium tank pressure maximum value EHM, and a second alarm situation for D1 comprises that the pressure value D1 of the helium tank pressure exceeds a predetermined second helium tank pressure maximum value ZHM, wherein ZHM>EHM, and the alarm messages for the first alarm situation for D1 and the second alarm situation for D1 are different.

49. The device according to claim 46, wherein an alarm situation comprises that a measured helium flow value exceeds a predetermined maximum helium flow value.

50. The device according to claim 49, wherein the predetermined maximum helium flow value depends on changes in the helium tank pressure that are currently or recently controlled, in particular wherein the maximum helium flow value is higher during and/or shortly after reductions made in the helium tank pressure than when the helium tank pressure is controlled to be constant.

51. The device according to claim 46, wherein an alarm situation comprises that a measured helium flow value falls below a predetermined minimum helium flow value.

52. The device according to claim 51, wherein the predetermined minimum helium flow value depends on current or recently controlled changes in the helium tank pressure.

53. The device according to claim 46, wherein an alarm situation comprises that a measured helium flow value is zero and at the same time a current position of the control valve is not closed.

54. The device according to claim 46, wherein an alarm situation comprises that a measured helium flow value is zero and at the same time a pressure value D2 in a helium recovery system has risen to the pressure value D1 in the helium tank.

55. The device according to claim 46, wherein an alarm situation comprises that a difference DHA=DHR-DAT of a measured pressure value DHR in a helium recovery system and a measured pressure value DAT in the ambient atmosphere (atm) exceeds a predetermined threshold value SWW.

56. The device according to claim 46, wherein at least some of the alarm situations take into account a current position of the control valve or a position of the control valve currently controlled by the closed-loop control device.

57. A method for regulating a pressure in a helium tank of an NMR magnet, the method comprising:
measuring a first pressure in the helium tank by a first pressure sensor;
measuring a second pressure outside the helium tank with at least one second pressure sensor;
adjusting an outflowing helium gas flow from the helium tank with a control valve; and
controlling the control valve with an electronic closed-loop control device that obtains first pressure values D1 measured by the first pressure sensor, and adjusts a position of the control valve depending on the measured first pressure values D1, so that the first pressure values D1 are adjusted to a predetermined setpoint value SW, and that obtains second pressure values D2 measured by the second pressure sensor, the electronic closed-loop control device, in a normal operation for NMR measurements, determining the setpoint SW depending on the measured first pressure values D1 and second pressure values D2, and changing the setpoint value SW for the pressure in the helium tank in steps as soon as a difference DIF=D1−D2 between the measured first pressure value D1 and the measured second pressure value D2 reaches or exceeds predetermined threshold values, wherein the setpoint value SW is raised by one step when the difference DIF becomes less than or equal to an increase threshold value HSW, and the setpoint value is lowered by one step when the difference DIF becomes greater than or equal to a decrease threshold value SSW, with HSW<SSW, a value of said one step being selected from the range 5-25 mbar.

58. The method according to claim 57, wherein the closed-loop control device, in a special operation for refilling liquid helium, transitions the setpoint value SW for the pressure in the helium tank to a target value ZW over a predetermined period of time, wherein the target value ZW is dependent on the second pressure value D2.

59. The method according to claim 58, wherein the closed-loop control device, in the special operation for refilling liquid helium, changes the setpoint value SW non-linearly over time, and wherein a helium flow through the control valve is kept approximately constant during the duration of the transfer of the setpoint value SW to the target value ZW.

60. The method according to claim 57, wherein an alarm message is automatically triggered by an alarm device in one or more predetermined alarm situations, including that a measured helium flow value of the outflowing helium gas stream from the helium tank through the control valve is zero at the same time that a current position of the control valve is not closed.

61. A cryostat arrangement, comprising:
a vacuum-insulated helium tank; and
a device according to claim 35, wherein the first pressure sensor is connected to the helium tank and the second pressure sensor is connected to a location outside the helium tank.

62. The cryostat arrangement according to claim 61, wherein the cryostat arrangement further comprises a helium recovery system connected to the outgoing helium line.

63. An NMR measuring arrangement, comprising:
a cryostat arrangement according to claim 61;
a superconducting NMR magnet in the helium tank of the cryostat arrangement;
an NMR probe head which projects into a room-temperature bore of the vacuum-insulated helium tank; and
an NMR spectrometer control device for controlling NMR measurements with the NMR probe head.

64. The NMR measuring arrangement according to claim 63, wherein the electronic closed-loop control device communicates a status of the regulation of the helium tank pressure to the NMR spectrometer control device, and wherein during times of pressure instability in the helium tank, the NMR spectrometer control device pauses the NMR measurements.
